(19) United States
(12) Patent Application Publication
(10) Pub. No.: US 2013/0329382 A1
(43) Pub. Date: Dec. 12, 2013

(54) FLEXIBLE PRINTED CIRCUIT BOARD AND DISPLAY DEVICE COMPRISING THE SAME

(71) Applicant: Chang Sub Jung, Hwaseong-si (KR)

(72) Inventor: Chang Sub Jung, Hwaseong-si (KR)

(21) Appl. No.: 13/913,715

(22) Filed: Jun. 10, 2013

(30) Foreign Application Priority Data
Jun. 12, 2012 (KR) 10-2012-0062770

(51) Int. Cl. H05K 1/02; H05K 7/06

(52) U.S. Cl. CPC H05K 1/0277; H05K 7/06
USPC 361/749; 174/251

(57) ABSTRACT

The flexible printed circuit board includes a plane part, a plurality of bending parts extending and bent from the plane part, wherein each of the plane part and the bending parts includes a base film, a wiring pattern, a cover film and a wiring pattern of the plane part and wiring patterns of the bending parts are electrically connected to each other. The display device including a display panel; one or more flexible printed circuit board electrically connected to the display panel; a main driving printed circuit board electrically connected to the flexible printed circuit board, wherein the one or more flexible printed circuit board includes a first part, a plurality of second parts extending from the first part, and each of the first parts and the second parts includes a base film, a wiring pattern, a cover film disposed on the base film and the wiring pattern.

### CLAIM OF PRIORITY

This application makes reference to, incorporates the same herein, and claims all benefits accruing under 35 U.S.C. §119 from an application for FLEXIBLE PRINTED CIRCUIT BOARD AND DISPLAY DEVICE COMPRISING THE SAME earlier filed in the Korean Intellectual Property Office on 12 Jun. 2012 and there duly assigned Serial No. 10-2012-0062770.

### BACKGROUND OF THE INVENTION

1. Field of the Invention

The present invention relates to a flexible printed circuit board and a display device comprising the flexible printed circuit board and more particularly, to a flexible printed circuit board which can minimize an elastic restoring force and a display device comprising the flexible printed circuit board.

2. Description of the Related Art

A flexible printed circuit board (FPCB) is easily bendable compared to a rigid PCB and has an advantage in that it can be utilized in a space where a general inflexible PCB cannot be installed, by forming one or both surfaces of a flexibly bendable base film.

Accordingly, various types of flexible printed circuit boards have being used to electrically connect a variety of display devices such as a liquid crystal display (LCD) or an organic light emitting diode (OLED) to various display panels.

In general, the FPCB is bent to be used to provide for an electrical connection between a display panel and a main driving printed circuit board for applying a particular signal to the display panel. Here, a strong elastic restoring force is applied to the bent FPCB, which may cause a defect such as delamination.

### SUMMARY OF THE INVENTION

The present invention provides a flexible printed circuit board which can minimize an elastic restoring force and a display device including the flexible printed circuit board.

The present invention also provides a flexible printed circuit board, which can prevent a defect, such as delamination, by minimizing an elastic restoring force of the flexible printed circuit board, and a display device comprising the flexible printed circuit board.

These and other objects of the present invention will be described in or be apparent from the following description of the preferred embodiments.

According to an aspect of the present invention, there is provided a display device including a display panel, a flexible printed circuit board electrically connected to the display panel, and a main driving printed circuit board electrically connected to the flexible printed circuit board, wherein the flexible printed circuit board includes a first part and a plurality of second parts extending from the first part, and each of the first part and the second parts includes a base film, a wiring pattern disposed on the base film and a cover film disposed on the base film and the wiring pattern.

According to another aspect of the present invention, there is provided a display device including a display panel, a plurality of flexible printed circuit boards electrically connected to the display panel, and a main driving printed circuit board electrically connected to the plurality of the flexible printed circuit boards, wherein each of the plurality of the flexible printed circuit boards includes a first part and a plurality of second parts extending from the first part, and each of the first parts and the second parts includes a base film, a wiring pattern disposed on the base film and a cover film disposed on the base film and the wiring pattern.

According to still another aspect of the present invention, there is provided a flexible printed circuit board including a plane part, and a plurality of bending parts extending and bent from the plane part, wherein each of the plane part and the plurality of the bending parts includes a base film, a wiring pattern disposed on the base film and a cover film disposed on the base film and the wiring pattern, and the a wiring pattern of the plane part and the wiring patterns of the bending parts are electrically connected to each other.

In some embodiment of the present invention, the first part may be electrically connected to the main driving printed circuit board, and the second parts may be electrically connected to the display panel.

In some embodiment of the present invention, the second parts may be electrically connected to a top surface of the display panel, and the main driving printed circuit board may be disposed at the rear side of the display panel.

In some embodiment of the present invention, the second parts may be bent from the top surface to the rear surface of the display panel along the side parts of the display panel.

In some embodiment of the present invention, the plurality of the second parts may be separated from each other and may be disposed on the same plane.

In some embodiment of the present invention, the widths of the plurality of second parts may be equal to each other.

In some embodiment of the present invention, the width of each of the plurality of the second parts may be 10 mm.

In some embodiment of the present invention, a plurality of driving integrated circuits (ICs) may be disposed on the first parts, wherein the plurality of driving ICs may be gate driving ICs or data driving ICs.

In some embodiment of the present invention, each of the plurality of driving ICs may be electrically connected to the main driving printed circuit board through the wiring patterns of the first parts.

In some embodiment of the present invention, a driving integrated circuit (IC) may be disposed on the plane part, wherein the driving IC may be electrically connected to the wiring patterns of the bending parts.

The embodiments of the present invention provide flexible printed circuit board which can minimize an elastic restoring force and a display device including the flexible printed circuit board.

The embodiments of the present invention also provide a flexible printed circuit board, which can prevent a defect, such as delamination, by minimizing an elastic restoring force of the flexible printed circuit board, and a display device comprising the flexible printed circuit board.

### BRIEF DESCRIPTION OF THE DRAWINGS

A more complete appreciation of the present invention, and many of the attendant advantages thereof, will be readily apparent as the present invention becomes better understood by reference to the following detailed description when considered in conjunction with the accompanying drawings in which like reference symbols indicate the same or similar components, wherein:

FIG. 1 is an exploded perspective view of a display device according to an embodiment of the present invention;

FIG. 2 is a top view of the display device shown in FIG. 1;

FIG. 3 is a rear view of the display device shown in FIG. 1;

FIG. 4 is a cross-sectional view of the display device shown in FIG. 1;

FIG. 5 is a plan view of a flexible printed circuit board according to an embodiment of the present invention;

FIG. 6 is an exploded perspective view of a display device according to another embodiment of the present invention;

FIG. 7 is a rear view of the display device shown in FIG. 6;

FIG. 8 is a cross-sectional view of the display device shown in FIG. 6;

FIG. 9 is a plan view of a flexible printed circuit board according to an embodiment of the present invention;

FIG. 10 is a rear view of a display device according to another embodiment of the present invention;

FIG. 11 is a schematic view for explaining an experimental example of a flexible printed circuit board according to an embodiment of the present invention; and

FIGS. 12 and 13 are graphs illustrating experimental examples of a flexible printed circuit board according to an embodiment of the present invention.

### DETAILED DESCRIPTION OF THE INVENTION

Advantages and features of the present invention and methods of accomplishing the same may be understood more readily by reference to the following detailed description of preferred embodiments and the accompanying drawings. The present invention, however, may be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Thus, in some embodiments, well-known structures and devices are not shown in order not to obscure the description of the invention with unnecessary detail. Like numbers refer to like elements throughout. In the drawings, the thickness of layers and regions are exaggerated for clarity.

It will be understood that when an element or layer is referred to as being “on,” or “connected to” another element or layer, it can be directly on or connected to the other element or layer or intervening elements or layers may be present. In contrast, when an element is referred to as being “directly on” or “directly connected to” another element or layer, there are no intervening elements or layers present. As used herein, the term “and/or” includes any and all combinations of one or more of the associated listed items.

Spatially relative terms, such as “below,” “beneath,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

Embodiments described herein will be described referring to plan views and/or cross-sectional views by way of ideal schematic views of the invention. Accordingly, the exemplary views may be modified depending on manufacturing technologies and/or tolerances. Therefore, the embodiments of the present invention are not limited to those shown in the views, but include modifications in configuration formed on the basis of manufacturing processes. Therefore, regions exemplified in figures have schematic properties and shapes of regions shown in figures exemplify specific shapes of regions of elements and not limit aspects of the present invention.

Embodiments of the present inventive concept will now be described with reference to the accompanying drawings.

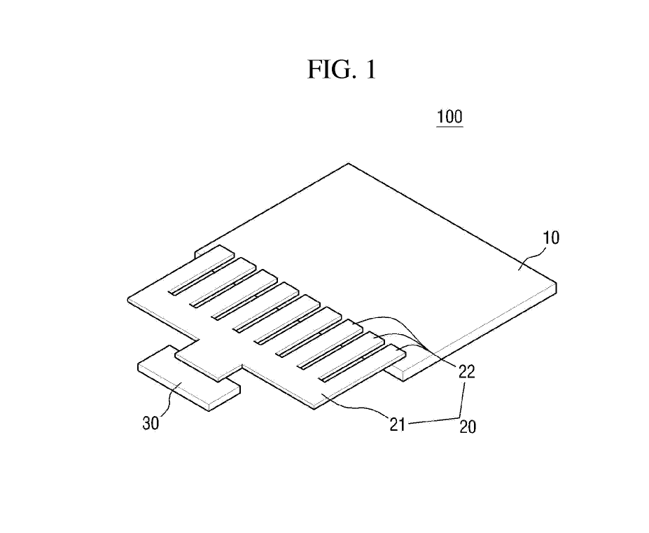

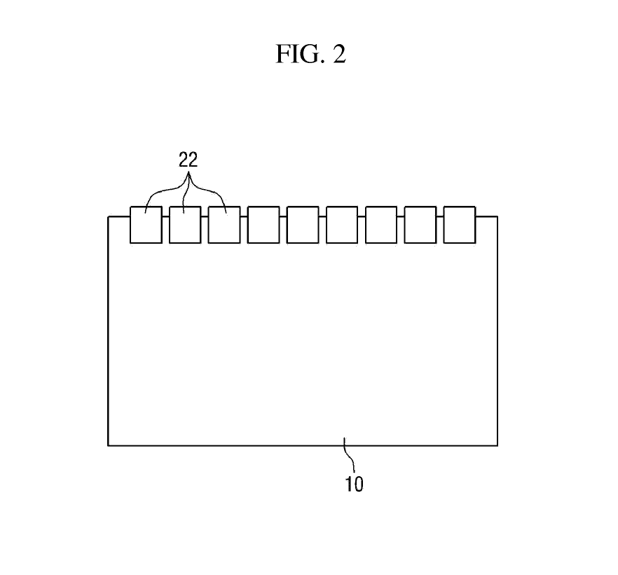

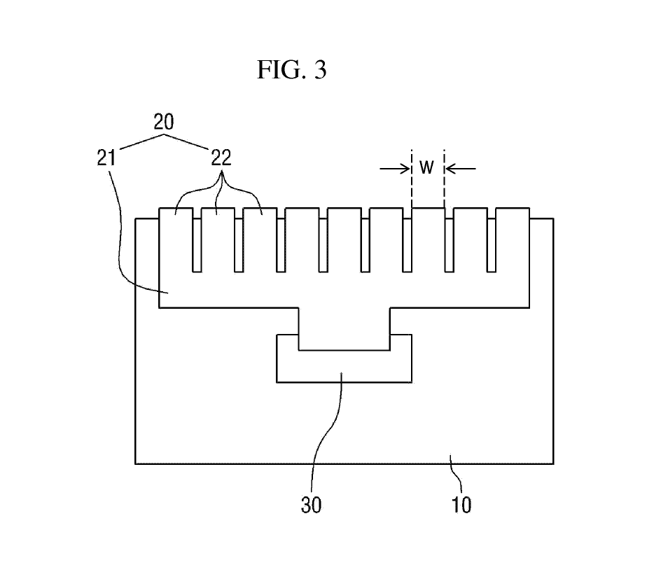

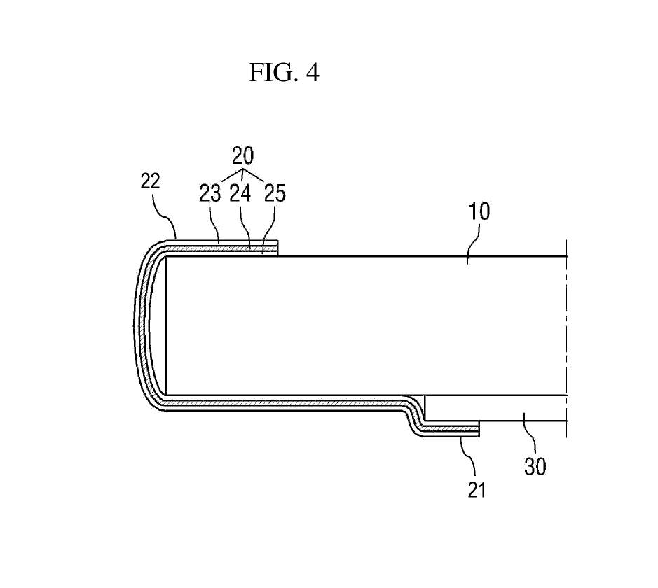

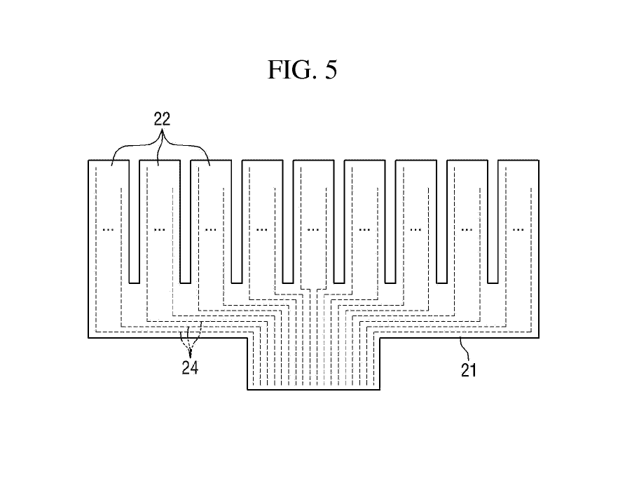

FIG. 1 is an exploded perspective view of a display device according to an embodiment of the present invention; FIG. 2 is a top view of the display device shown in FIG. 1; FIG. 3 is a rear view of the display device shown in FIG. 1; FIG. 4 is a cross-sectional view of the display device shown in FIG. 1; and FIG. 5 is a plan view of a flexible printed circuit board according to an embodiment of the present invention.

The display device 100 may include a display panel 10, a flexible printed circuit board (FPCB) 20, and a main driving printed circuit board (PCB) 30.

The display panel 10 is a panel of displaying an image, and may include a panel such as a liquid crystal display (LCD) panel, an electrophoretic display panel, an organic light emitting diode (OLED) panel, an LED panel, an inorganic electroluminescent (EL) display panel, a field emission display (FED) panel, a surface-conduction electron-emitter display (SED) panel, a plasma display panel (PDP), a cathode ray tube (CRT) display panel, and so on.

The main driving PCB 30 is a circuit board that supplies a driving signal to the display panel 10. The main driving PCB 30 may include a timing controller (not shown) that generates a control signal for driving the display panel 10, and a power supply voltage generator (not shown) that generates a power supply voltage.

The main driving PCB 30 may be disposed at the rear surface of the display panel 10. Since the display panel 10 generally displays an image to a top surface of the display panel 10, the rear surface of the display panel 10 is a region that is invisible to a user. Therefore, in order to maximize space efficiency and to conceal a component that is not necessarily viewed by the user, the main driving PCB 30 may be disposed at the rear side of the display panel 10. For the sake of convenient explanation, FIGS. 1 to 4 illustrate that the main driving PCB 30 is disposed at the rear side of the display panel 10. However, in some embodiments of the present invention, the main driving PCB 30 may be disposed at the rear surface of the display panel 10.

Since the main driving PCB 30 is a circuit board for supplying a driving signal to the display panel 10, it is necessary to electrically connect the main driving PCB 30 to the display panel 10. Therefore, it is necessary to provide a component for providing electrical connection between the display panel 10 and the main driving PCB 30, and the FPCB 20 is generally used as the component for providing the electrical connection.

The FPCB 20 is electrically connected to the display panel 10 and is also electrically connected to the main driving PCB 30, thereby providing electrical connection between the display panel 10 and the main driving PCB 30. For example, one end of the FPCB 20 is electrically connected to the display panel 10 and the opposite end of the FPCB 20 is electrically connected to the main driving PCB 30. The display panel 10 and the main driving PCB 30 may be electrically connected through the inside of the FPCB 20.

In view of section, the FPCB 20 may include a base film 25, a wiring pattern 24 disposed on the base film 25 and a cover film 23 disposed on the base film 25 and the wiring pattern 24.

The base film 25 and the cover film 23 may be formed using the same material. In some embodiments of the present invention, the base film 25 and the cover film 23 may be formed of a film having good flexibility, insulating property and heat resistance, for example, polyimide.

The wiring pattern 24 may be disposed between the base film 25 and the cover film 23. The wiring pattern 24 is provided for transmitting a predetermined electrical signal and may be made of a metal, such as copper (Cu). Alternatively, tin (Sn), silver (Ag) or nickel (Ni) may be plated on a surface of copper (Cu). The wiring pattern 24 may be formed by casting, laminating, electroplating, and others. The wiring pattern 24 may later be described in more detail.

The FPCB 20 may include a first part 21 and a plurality of second parts 22 extending from the first part 21. In the FPCB 20, the first part 21 corresponds to a plane part and may be electrically connected to the main driving PCB 30. In the FPCB 20, the second parts 22 correspond to bending parts, and may be electrically connected to the display panel 10.

Referring to FIGS. 1 to 5, the FPCB 20 may include a polygonal first part 21 and a plurality of polygonal second parts 22 extending from the first part 21. As described above, since the main driving PCB 30 may be disposed at the rear surface of the display panel 10 and the first part 21 may be electrically connected to the main driving PCB 30, the first part 21 may also be disposed at the rear surface of the display panel 10. In addition, since the second parts 22 may be electrically connected to the top surface of the display panel 10, one ends of the second parts 22 may be disposed on the top surface of the display panel 10. Therefore, the second parts 22 may be bent from the top surface to the rear surface of the display panel 10 along the sides of the display panel 10 and opposite ends of the second parts 22 may be electrically connected to the first part 21.

In order to provide an electrical connection, via holes (not shown) may be formed in the first part 21 and the second parts 22 of the FPCB 20. For example, the display panel 10 and the second parts 22 may provide an electrical connection between the display panel 10 and the wiring pattern 24 of the second parts 22 through the via holes formed in the second parts 22, and the first part 21 and the main driving PCB 30 may provide an electrical connection therebetween through the via holes formed in the first part 21. In addition, since the first part 21 and the second parts 22 of the FPCB 20 may provide the electrical connection such that the wiring pattern 24 of the first part 21 and the wiring pattern 24 of the second parts 22 are electrically connected to each other.

The plurality of second parts 22 of the FPCB 20, that is, the plurality of bending parts 22, extend from the first part 21 and separated from each other to then be disposed on the same plane. In some embodiments, widths w of the plurality of second parts 22 are equal to each other, and may be approximately 10 mm. In the display device 100 according to an embodiment of the present invention, bending parts of the FPCB 20 correspond to parts of the plurality of second parts 22 separated from each other, rather than integrally formed parts of the FPCB 20, thereby reducing an elastic restoring force of the FPCB 20 and preventing a defect, such as delamination.

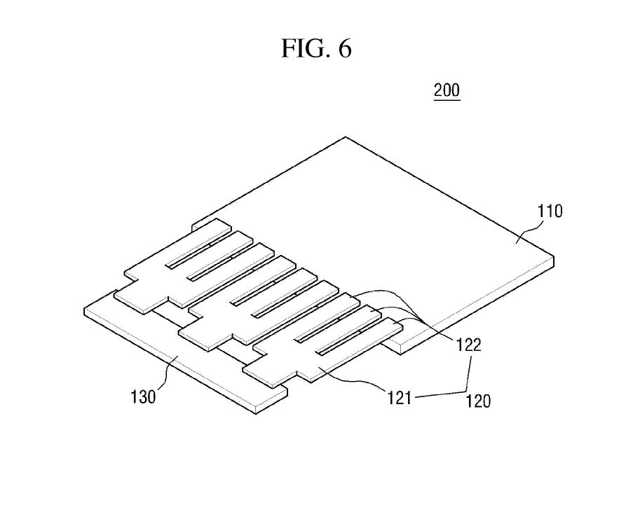

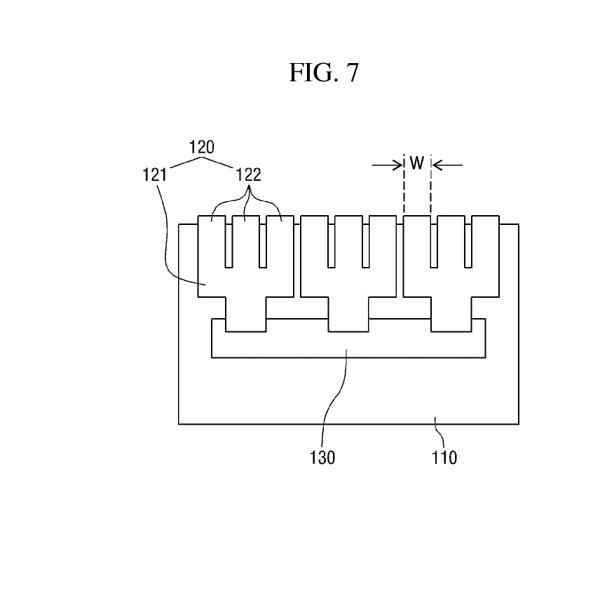

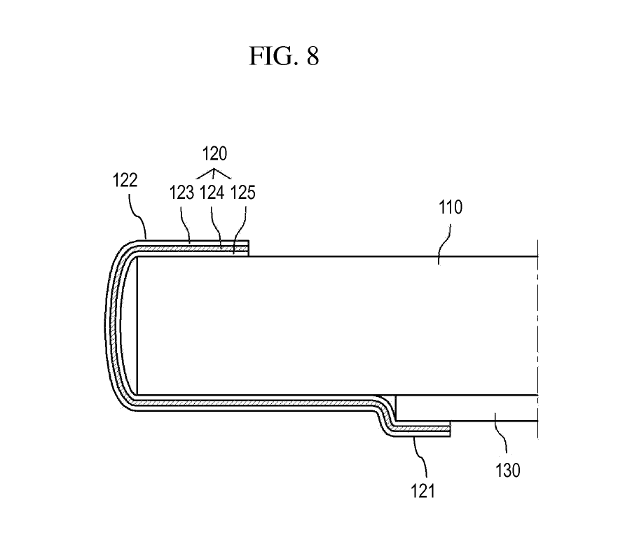

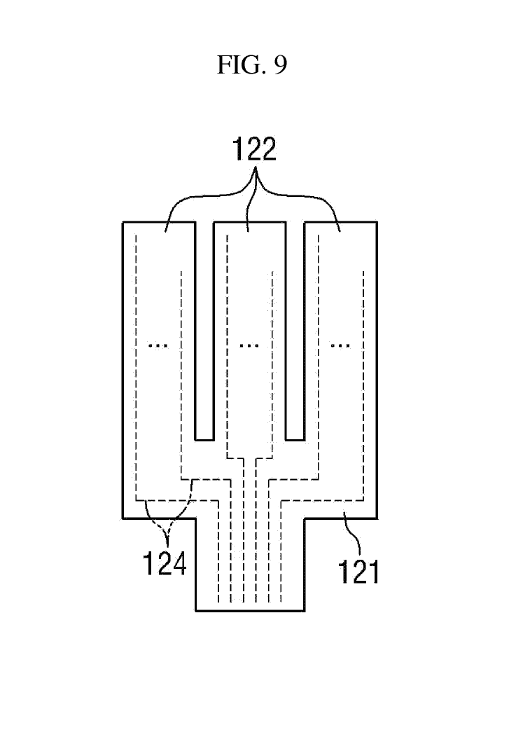

FIG. 6 is an exploded perspective view of a display device according to another embodiment of the present invention; FIG. 7 is a rear view of the display device shown in FIG. 6; FIG. 8 is a cross-sectional view of the display device shown in FIG. 6; and FIG. 9 is a plan view of a flexible printed circuit board according to an embodiment of the present invention.

The display device 200 includes a display panel 110, a plurality of flexible printed circuit boards 120 and a main driving PCB 130.

The display panel 110 and the main driving PCB 130 are substantially the same as the display panel 10 and the main driving PCB 30 shown in FIGS. 1 to 5, and repeated descriptions thereof will not be given.

The plurality of the flexible printed circuit boards 120 may be electrically connected to the display panel 110 and to the main driving PCB 130, thereby providing an electrical connection between the display panel 110 and the main driving PCB 130. For example, one ends of the plurality of the flexible printed circuit boards 120 may be electrically connected to the display panel 110 and opposite ends thereof 120 may be electrically connected to the main driving PCB 130. The display panel 110 and the main driving PCB 130 may be electrically connected through the inside of the flexible printed circuit boards 120. For the sake of convenient explanation, FIGS. 6 to 9 illustrate three of the plurality of the flexible printed circuit boards 120, but the number of the flexible printed circuit boards 120 is not limited thereto. The number of the flexible printed circuit boards 120 may vary.

In view of section, each of the flexible printed circuit boards 120 may include a base film 125, a wiring pattern 124 disposed on the base film 125 and a cover film 123 disposed on the base film 125 and the wiring pattern 124.

Each of the plurality of the flexible printed circuit boards 120 may include a first part 121 and a plurality of second parts 122 extending from the first part 121. In each of the plurality of the flexible printed circuit boards 120, the first part 121 corresponds to a plane part and may be electrically connected to the main driving PCB 130. In each of the plurality of the flexible printed circuit boards 120, the second parts 122 correspond to bending parts and may be electrically connected to the display panel 110.

The plurality of the second parts 122 of the flexible printed circuit boards 120, that is, the plurality of the bending parts 122, extend from the first part 121 and separated from each other to then be disposed on the same plane. In some embodiments, widths w of the plurality of second parts 122 may be equal to each other, and may be approximately 10 mm. In the display device 200 according to another embodiment of the present invention, bending parts of the flexible printed circuit boards 120 correspond to parts of the plurality of second parts 122 separated from each other, rather than integrally formed parts of the flexible printed circuit boards 120, thereby reducing an elastic restoring force of the FPCB 120 and preventing a defect, such as delamination.

The plurality of the flexible printed circuit boards 120 shown in FIGS. 6 to 9 may perform substantially the same functions as those of the flexible printed circuit board 20 shown in FIGS. 1 to 5. That is to say, three of the plurality of the flexible printed circuit boards 120 shown in FIGS. 6 to 9 may perform substantially the same functions as those of the one flexible printed circuit board 20 shown in FIGS. 1 to 5. Since the plurality of the flexible printed circuit boards 120 shown in FIGS. 6 to 9 are substantially the same as the flexible printed circuit board 20 shown in FIGS. 1 to 5, except that they are formed by separating the flexible printed circuit board 20 shown in FIGS. 1 to 5 into a plurality of flexible printed circuit boards 120, repeated descriptions thereof will not be given.

FIG. 9 is a rear view of a display device according to another embodiment of the present invention. The display device 200 may include a plurality of driving integrated circuits (ICs) 140.

The plurality of the driving ICs 140 may be gate driving ICs for applying a gate signal to the display panel 110 or data driving ICs for applying a data signal to the display panel 110. The plurality of the driving ICs 140 may be mounted on the plurality of the flexible printed circuit boards 120, specifically on the first parts 121, that is, plane parts, of the plurality of the flexible printed circuit boards 120. When the plurality of the driving ICs 140 are mounted on the first parts 121 of the plurality of the flexible printed circuit boards 120, the plurality of the driving ICs 140 may be electrically connected to the wiring patterns 124 of the plurality of the flexible printed circuit boards 120, and the plurality of the driving ICs 140 may receive an electrical signal from the main driving PCB 130 and may apply a gate signal or a data signal to the display panel 110 through the wiring patterns 124.

The number of the plurality of the driving ICs 140 may be equal to that of the plurality of the flexible printed circuit boards 120. One driving IC 140 may be disposed on one FPCB 120, and the wiring pattern 124 electrically connected to one driving IC 140 may exist in only one FPCB 120.

The present invention will be described in more detail through the following specific experimental examples, contents that are not described herein are technically inferred by those skilled in the relevant art and detailed description thereof will not be given.

### Experimental Example

### Measurement of Elastic Restoring Force of Flexible Printed Circuit Board (FPCB)

The elastic restoring force of a flexible printed circuit board (FPCB) depending on the shape was measured as follows.

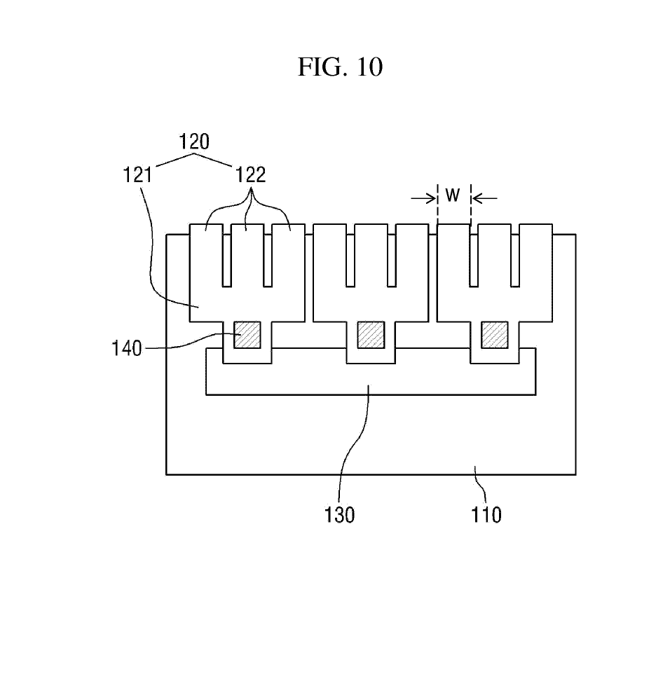

Referring to FIG. 10, the flexible printed circuit board was made to be shaped of a cylinder having a diameter of 10 mm, the bottom surface of the cylinder was adhered using a double sided tape for fixing and was then compressed using Instron equipment to have a radius of curvature. In such a manner, a compressive force depending on displacement was measured to observe the elastic restoring force of the FPCB.

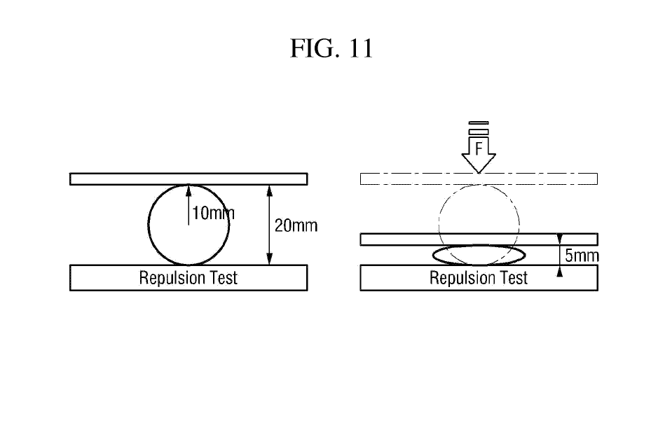

Comparative Example illustrates measurement of compressive forces applied to integrally formed type FPCB, which are integrally formed. In Comparative Example, the compressive forces of the integrally formed type FPCBs were measured while increasing base panel widths of the integrally formed type FPCBs. As shown in Table 1 and FIG. 11, the integrally formed type FPCBs demonstrated second order linear compressive forces according to the increase in the width. The integrally formed type FPCB is an FPCB that the plurality of second parts 122 of the FPCB are not separated from each other.

TABLE 1

| | 10 mm base | 20 mm base | 30 mm base |
|---|---|---|---|
| | board width | board width | board width |
| Comparative | 44 gf | 94 gf | 150 gf |
| Example | | | |

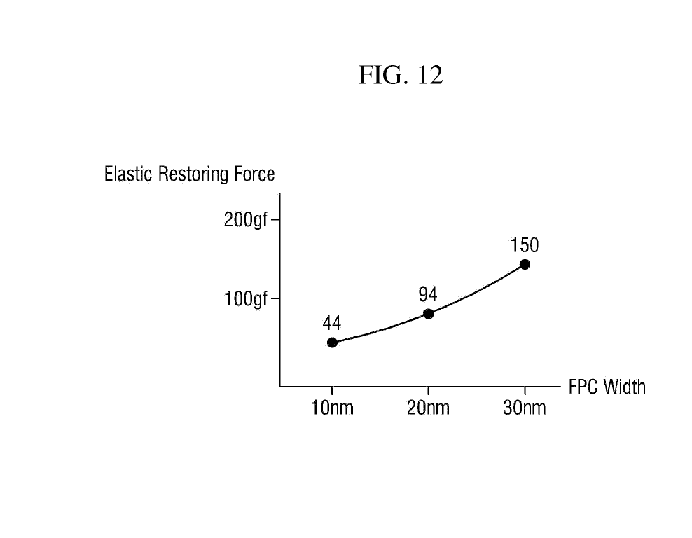

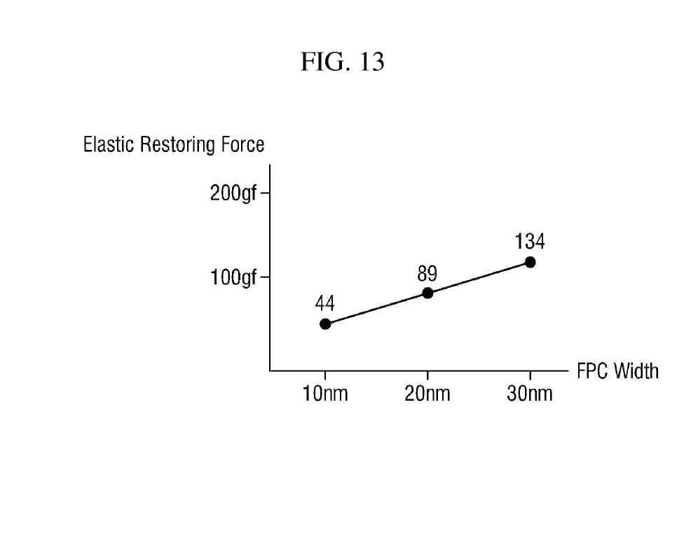

Experimental Example illustrates measurement of compressive forces applied to separation type FPCBs, like the FPCB according to an embodiment of the present invention. In Experimental Example, the compressive forces of a plurality of unit FPCBs each having the same width were measured. In order the overall width of the FPCBs, the number of unit FPCBs each having the same width was increased and elastic restoring forces of the FPCBs were then measured. As shown in Table 2 and FIG. 12, the separation type FPCBs demonstrated first order linear compressive forces according to the increase in the width. The separation type FPCB is an FPCB that the plurality of second parts 122 of the FPCB are separated from each other.

TABLE 2

| | 10 mm base | 20 mm base | 30 mm base |
|---|---|---|---|
| | panel width | panel width | panel width |
| | (One 10 mm | (Two 10 mm | (Three 10 mm |
| | board) | boards) | boards) |
| Experimental | 44 gf | 89 gf | 134 gf |
| Example | | | |

Based on the results of experimental examples shown in Tables 1 and 2 and FIGS. 11 and 12, the elastic restoring forces of the FPCBs depending on the shape will now be described. That is to say, while the elastic restoring forces of the integrally formed type FPCBs increased with secondly linearity as the widths thereof increased, the elastic restoring forces of the separation type FPCBs increased with firstly linearity as the widths thereof increased. In addition, when the elastic restoring forces of a 30 mm wide integrally formed type FPCB and a 30 mm wide separation type FPCB were compared, the elastic restoring force could be reduced by approximately 11% by using three FPCBs each having a width of 10 mm, rather than using one FPCB having a width of 30 mm.

While the present invention has been particularly shown and described with reference to exemplary embodiments thereof, it will be understood by those of ordinary skill in the art that various changes in form and details may be made therein without departing from the spirit and scope of the present invention as defined by the following claims. It is therefore desired that the present embodiments be considered in all respects as illustrative and not restrictive, reference being made to the appended claims rather than the foregoing description to indicate the scope of the invention.

What is claimed is:

1. A display device comprising:
a display panel;
a flexible printed circuit board electrically connected to the display panel; and
a main driving printed circuit board electrically connected to the flexible printed circuit board,
wherein the flexible printed circuit board comprises a first part and a plurality of second parts extending from the first part, and each of the first part and the second parts comprises a base film, a wiring pattern disposed on the base film and a cover film disposed on the base film and the wiring pattern.

2. The display device of claim 1, wherein the first part is electrically connected to the main driving printed circuit board, and the second parts are electrically connected to the display panel.

3. The display device of claim 2, wherein the second parts are electrically connected to a top surface of the display panel, and the main driving printed circuit board is disposed at the rear side of the display panel.

4. The display device of claim 3, wherein the second parts are bent from the top surface to the rear surface of the display panel along the side parts of the display panel.

5. The display device of claim 1, wherein the plurality of the second parts are separated from each other and are disposed on the same plane.

6. The display device of claim 1, wherein the widths of the plurality of second parts are equal to each other.

7. The display device of claim 6, wherein the width of each of the plurality of the second parts is 10 mm.

8. A display device comprising:
a display panel;
a plurality of flexible printed circuit boards electrically connected to the display panel; and
a main driving printed circuit board electrically connected to the plurality of the flexible printed circuit boards,
wherein each of the plurality of the flexible printed circuit boards comprises a first part and a plurality of second parts extending from the first part, and each of the first parts and the second parts comprises a base film, a wiring pattern disposed on the base film and a cover film disposed on the base film and the wiring pattern.

9. The display device of claim 8, wherein the first parts are electrically connected to the main driving printed circuit board, and the second parts are electrically connected to the display panel.

10. The display device of claim 9, wherein the second parts are electrically connected to a top surface of the display panel, and the main driving printed circuit board is disposed at the rear side of the display panel.

11. The display device of claim 10, wherein the second parts are bent from the top surface to the rear surface of the display panel along the side parts of the display panel.

12. The display device of claim 8, further comprising a plurality of driving integrated circuits (ICs) disposed on the first parts, wherein the plurality of driving ICs are gate driving ICs or data driving ICs.

13. The display device of claim 12, wherein each of the plurality of driving ICs is electrically connected to the main driving printed circuit board through the wiring patterns of the first parts.

14. The display device of claim 8, wherein the plurality of the second parts are separated from each other and are disposed on the same plane.

15. The display device of claim 8, wherein the widths of the plurality of the second parts are equal to each other.

16. The display device of claim 15, wherein the width of each of the plurality of the second parts is 10 mm.

17. A flexible printed circuit board comprising:
a plane part; and
a plurality of bending parts extending and bent from the plane part,
wherein each of the plane part and the plurality of the bending parts comprises a base film, a wiring pattern disposed on the base film and a cover film disposed on the base film and the wiring pattern, and
the wiring pattern of the plane part and the wiring patterns of the bending parts are electrically connected to each other.

18. The flexible printed circuit board of claim 17, further comprising a driving integrated circuit (IC) disposed on the plane part, wherein the driving IC is electrically connected to the wiring patterns of the bending parts.

19. The flexible printed circuit board of claim 18, wherein the plurality of the second parts are separated from each other and are disposed on the same plane.

20. The flexible printed circuit board of claim 18, wherein widths of the plurality of the second parts are equal to each other.

21. The flexible printed circuit board of claim 17, wherein the width of each of the plurality of second parts is 10 mm.
